(19) United States
(12) Patent Application Publication
(10) Pub. No.: US 2025/0107399 A1
(43) Pub. Date: Mar. 27, 2025

(54) DISPLAY DEVICE AND METHOD FOR DETECTING THE POSITION OF THE ENCAPSULATION FILM THEREOF

(71) Applicant: Samsung Display Co., LTD., Yongin-si (KR)

(72) Inventors: Dae Hong KIM, Yongin-si (KR); Jeong Moon LEE, Yongin-si (KR)

(73) Assignee: Samsung Display Co., LTD., Yongin-si (KR)

(21) Appl. No.: 18/731,793

(22) Filed: Jun. 3, 2024

(30) Foreign Application Priority Data
Sep. 27, 2023 (KR) 10-2023-0131150

(51) Int. Cl. H10K 59/80; H10K 59/12

(52) U.S. Cl. CPC H10K 59/873; H10K 59/1201; H10K 59/8792

(57) ABSTRACT

According to an embodiment of the disclosure, a display device includes a display area and a non-display area; a pixel electrode disposed on a substrate in the display area; a light emitting layer disposed on the pixel electrode; a common electrode disposed on the light emitting layer, an encapsulation organic film disposed on the common electrode; and a detection pattern disposed in the non-display area.

### CROSS-REFERENCE TO RELATED APPLICATION

This application claims priority to and benefits of Korean Patent Application No. 10-2023-0131150 under 35 U.S.C. § 119, filed on Sep. 27, 2023 in the Korean Intellectual Property Office (KIPO), the entire contents of which are incorporated herein by reference.

### BACKGROUND

### 1. Technical Field

The disclosure relates to a display device, and more particularly, to a display device that allows accurate detection of a position of an edge of an encapsulation organic film, and a method for detecting a position of an encapsulation film thereof.

### 2. Description of the Related Art

Organic light emitting diode displays have self-luminous properties and do not require separate light sources unlike liquid crystal displays, and may have a reduced thickness and weight. In addition, the organic light emitting diode displays have attracted attention as next-generation display devices for portable electronic devices because they exhibit high-quality characteristics such as low power consumption, high luminance, and a high response speed.

### SUMMARY

Aspects of the disclosure provide a display device that allows accurate detection of a position of an edge of an encapsulation organic film, and a method for detecting a position of an encapsulation film thereof.

According to an embodiment of the disclosure, a display device includes a display area and a non-display area; a pixel electrode disposed on a substrate in the display area; a light emitting layer disposed on the pixel electrode; a common electrode disposed on the light emitting layer; an encapsulation organic film disposed on the common electrode; and a detection pattern disposed in the non-display area.

In an embodiment, at least a portion of the detection pattern overlaps the encapsulation organic film.

In an embodiment, the detection pattern has a black color.

In an embodiment, the detection pattern includes at least one of chromium, molybdenum, black ink or black dye, carbon black, lactam black, perylene black, and aniline black.

In an embodiment, the detection pattern includes a plurality of sub-patterns spaced apart from each other.

In an embodiment, further comprising a dam disposed in the non-display area.

In an embodiment, the dam is disposed in the non-display area of the substrate so as to surround the display area.

In an embodiment, the dam includes a first dam disposed in the non-display area so as to surround the display area; and a second dam disposed in the non-display area of the substrate so as to surround the first dam.

In an embodiment, the detection pattern is disposed between the display area and the dam.

In an embodiment, the detection pattern has a smaller height or a smaller thickness than the dam.

In an embodiment, the encapsulation organic film includes a monomer.

According to an embodiment of the disclosure, a method for detecting a position of an encapsulation film of a display device, comprising: preparing a display panel including a substrate, a pixel electrode disposed on the substrate, a light emitting layer disposed on the pixel electrode, a common electrode disposed on the light emitting layer, and an encapsulation organic film disposed on the common electrode; irradiating ultraviolet to the encapsulation organic film; capturing an image of the encapsulation organic film in a state in which the ultraviolet is irradiated to the encapsulation organic film; and confirming the encapsulation organic film based on the captured image.

In an embodiment, the irradiating of the ultraviolet includes irradiating near ultraviolet.

In an embodiment, in the confirming of the encapsulation organic film, a position of an edge of the encapsulation organic film on the substrate is confirmed in the captured image.

In an embodiment, further comprising forming a detection pattern in a non-display area.

In an embodiment, in the confirming of the encapsulation organic film, a position of an edge of the encapsulation organic film on the substrate is confirmed based on the detection pattern in the captured image.

In an embodiment, in the confirming of the encapsulation organic film, the position of the edge of the encapsulation organic film is confirmed based on an overlapping portion of the detection pattern that overlaps the encapsulation organic film and a non-overlapping portion of the detection pattern that does not overlap the encapsulation organic film in the captured image.

In an embodiment, the overlapping portion of the detection pattern is displayed blurrier than the non-overlapping portion of the detection pattern in the captured image.

In an embodiment, the encapsulation organic film includes a monomer.

In an embodiment, the detection pattern includes at least one of chromium, molybdenum, black ink or black dye, carbon black, lactam black, perylene black, and aniline black.

With a display device and a method for detecting a position of an encapsulation film thereof according to the disclosure, a position of an edge of an encapsulation organic film may be accurately detected.

The effects of the disclosure are not limited to the above-described effects and other effects which are not described herein will become apparent to those skilled in the art from the following description.

### BRIEF DESCRIPTION OF THE DRAWINGS

The above and other aspects and features of the disclosure will become more apparent by describing in detail example embodiments thereof with reference to the attached drawings, in which:

FIG. 1 is a schematic plan view of a display device according to an example embodiment;

FIG. 2 is a schematic plan view of a unit pixel of FIG. 1 in more detail;

FIG. 3 is a schematic cross-sectional view taken along line II-II′ of FIG. 2;

FIG. 4 is a schematic cross-sectional view of the display device according to an example embodiment taken along line I-I′ of FIG. 1;

FIG. 5 is a schematic cross-sectional view of the display device according to an example embodiment taken along line I-I′ of FIG. 1;

FIG. 6 is a schematic view for describing a method for inspecting a spread degree of an encapsulation organic film according to an example embodiment;

FIG. 7 is a schematic plan view of a display device according to an example embodiment;

FIG. 8 is a schematic enlarged view of part A of FIG. 7;

FIG. 9 is a schematic cross-sectional view taken along line III-III′ of FIG. 8;

FIG. 10 is a schematic view for describing a method for deciding a position of an encapsulation organic film using a detection pattern of FIG. 8;

FIG. 11 is a schematic enlarged view of a portion of a display device according to an example embodiment;

FIG. 12 is a schematic cross-sectional view taken along line IV-IV′ of FIG. 11;

FIG. 13 is a schematic view for describing a method for deciding a position of an encapsulation organic film using a detection pattern of FIG. 11;

FIG. 14 is a schematic enlarged view of a portion of a display device according to an example embodiment; and

FIG. 15 is a schematic enlarged view of a portion of a display device according to an example embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will convey the scope of the disclosure to those skilled in the art.

It will also be understood that when a layer is referred to as being “on” another layer or substrate, it can be directly on the other layer or substrate, or one or more intervening layers may also be present. The same reference numbers and/or characters may indicate the same components throughout the specification. In the attached figures, the thickness of layers and regions may be exaggerated for clarity.

Although the terms “first”, “second”, etc. may be used herein to describe various elements, these elements should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the disclosure may be combined partially or totally. As will be clearly appreciated by those skilled in the art, technically various interactions and operations are possible. Various embodiments can be practiced individually or in combination.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, specific example embodiments will be described with reference to the accompanying drawings.

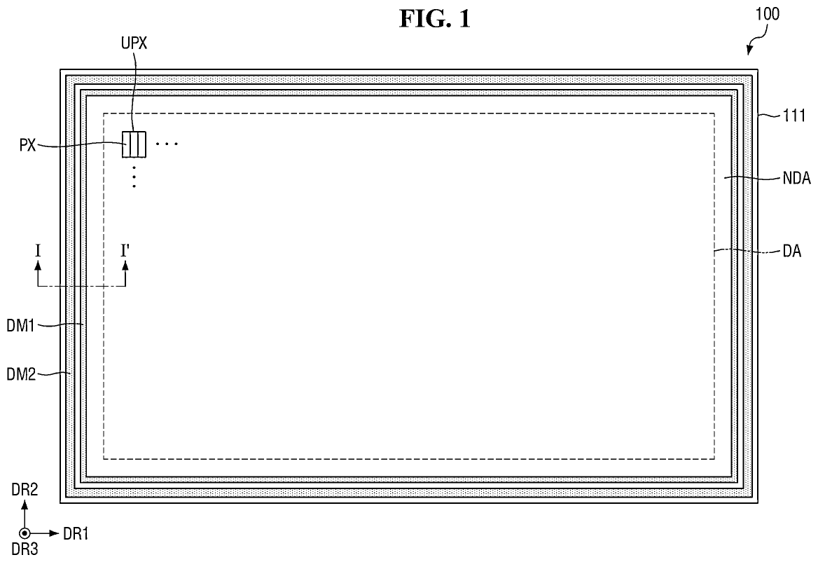

FIG. 1 is a schematic plan view of a display device according to an example embodiment.

The display device may include a display panel 100, as illustrated in FIG. 1.

The display panel 100 may include a display area DA and a non-display area NDA. For example, the display panel 100 may include a substrate 111, and the substrate 111 of the display panel 100 may include a display area DA and a non-display area NDA. The display area DA may be surrounded by the non-display area NDA.

The display area DA may include one or more pixels PX. Three adjacent pixels PX may form one unit pixel UPX. In other words, the unit pixel UPX may include three pixels PX providing light of different colors. For example, the unit pixel UPX may include a red pixel providing red light, a green pixel providing green light, and a blue pixel providing blue light.

The non-display area NDA may be disposed at an edge of the substrate 111 or the display panel 100. At least one dam may be disposed in the non-display area NDA. For example, a first dam DM1 and a second dam DM2 may be disposed in the non-display area NDA.

The first dam DM1 may have a closed shape (e.g., a closed curve shape) surrounding the display area DA. In plan view, the first dam DM1 may be disposed between the display area DA and the second dam DM2.

The second dam DM2 may have a closed shape (e.g., a closed curve shape) surrounding the first dam DM1. In plan view, the second dam DM2 may be disposed between the edge of the substrate 111 and the first dam DM1. The second dam DM2 and the first dam DM1 may have different widths. For example, as illustrated in FIG. 1, the second dam DM2 may have a greater width than the first dam DM1. Here, the width may refer to a size in a first direction DR1 or a second direction DR2.

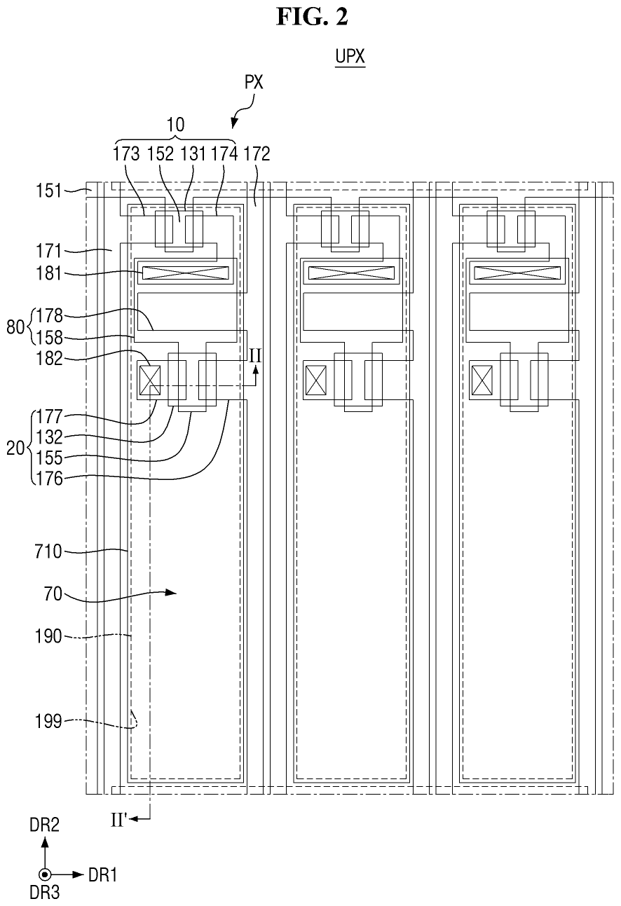

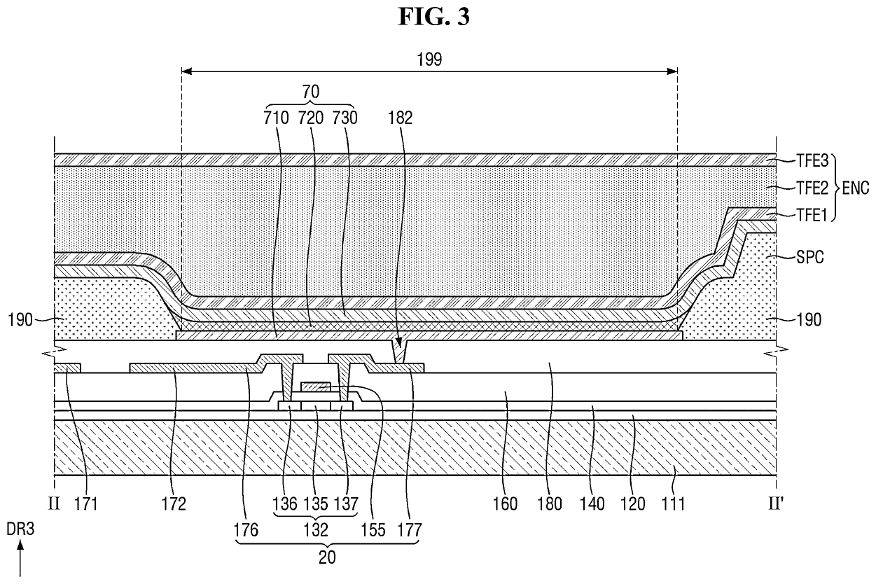

Hereinafter, a pixel of a light emitting display device according to an example embodiment will be mainly described below with reference to FIGS. 2 and 3.

FIG. 2 is a schematic plan view of a unit pixel UPX of FIG. 1 in more detail, and FIG. 3 is a schematic cross-sectional view taken along line II-II′ of FIG. 2.

A switching transistor 10, a driving transistor 20, a capacitor element 80, and a light emitting element 70 formed for each pixel PX may be disposed on the substrate 111. Here, the light emitting element 70 may be, for example, an organic light emitting diode (OLED). A gate line 151, a data line 171, and a common power line 172 may be disposed on the substrate 111. The gate line 151 may be disposed in a direction, and the data line 171 and common power line 172 may be insulated from and intersect the gate line 151. Here, a pixel may be defined with the gate line 151, the data line 171, and the common power line 172 as a boundary, but is not necessarily limited thereto.

The light emitting element 70 may include a pixel electrode 710, a light emitting layer 720 disposed on the pixel electrode 710, and a common electrode 730 disposed on the light emitting layer 720. Here, the pixel electrode 710 may correspond to a positive (+) electrode, which is a hole injection electrode, and the common electrode 730 may correspond to a negative (−) electrode, which is an electron injection electrode. However, the disclosure is not necessarily limited thereto, and depending on a method for driving the display device, the pixel electrode 710 may correspond to a negative electrode and the common electrode 730 may correspond to a positive electrode.

Holes and electrons may be injected into an organic light emitting layer 720 from the pixel electrode 710 and the common electrode 730, respectively. Light may be emitted in case that excitons, which are combinations of the injected holes and electrons, fall from an excited state to a ground state.

The display device according to an example embodiment may display an image by the light emitting element 70 emitting light from the light emitting layer 720 in a direction opposite to a direction toward the pixel electrode 710, for example, in a direction toward the common electrode 730. In other words, the display device according to an example embodiment may be a top emission-type display device. However, embodiments are not limited thereto, and the display device may be another type display device within the spirit and scope of the disclosure.

The capacitor element 80 may include a first capacitor plate 158 and a second capacitor plate 178 disposed with a gate insulating film 140 interposed therebetween. Here, the gate insulating film 140 may function as a dielectric of the capacitor element 80. In the capacitor element 80, capacitance of the capacitor element 80 may be determined by stored charges and a voltage between the first and second capacitor plates 158 and 178.

The switching transistor 10 may include a switching semiconductor layer 131, a switching gate electrode 152, a switching source electrode 173, and a switching drain electrode 174, and the driving transistor 20 may include a driving semiconductor layer 132, a driving gate electrode 155, a driving source electrode 176, and a driving drain electrode 177.

The switching transistor 10 may function as a switching element selecting a pixel that is to emit light. The switching gate electrode 152 may be connected to the gate line 151. The switching source electrode 173 may be connected to the data line 171. The switching drain electrode 174 may be disposed to be spaced apart from the switching source electrode 173, and may be connected to the first capacitor plate 158 through a contact hole 181.

The driving transistor 20 may apply driving power for causing the light emitting layer 720 of the light emitting element 70 in the selected pixel to emit light to the pixel electrode 710. The driving gate electrode 155 may be connected to the first capacitor plate 158. Each of the driving source electrode 176 and the second capacitor plate 178 may be connected to the common power line 172. The driving drain electrode 177 may be connected to the pixel electrode 710 of the light emitting element 70 through a contact hole 182.

With such a structure, the switching transistor 10 may be turned on by a gate voltage applied to the gate line 151, and a data voltage from the data line 171 may be transferred to the driving transistor 20 by the turned-on switching transistor 10. A differential voltage corresponding to a difference between a common voltage applied from the common power line 172 to the driving transistor 20 and the data voltage transferred from the switching transistor 10 may be stored in the capacitor element 80, and a current corresponding to the voltage stored in the capacitor element 80 may flow to the light emitting device 70 through the driving transistor 20, such that the light emitting device 70 may emit light.

Hereinafter, a structure of the display device according to an example embodiment will be described in detail according to stacking order. Hereinafter, a structure of a transistor will be described focusing on the driving transistor 20. A difference between the switching transistor 10 and the driving transistor 20 will be briefly described.

The substrate 111 may be an insulating substrate 111 including, e.g., glass, quartz, ceramic, plastic, or the like, but is not limited thereto. The term “include” and its variations as used herein may mean “contain” and/or “be made of.” For example, the substrate 111 may be a metallic substrate 111 including stainless steel or the like.

A buffer layer 120 may be disposed on the substrate 111. The buffer layer 120 serves to prevent permeation of impurity elements and planarize a surface, and may include various materials that may perform such a role. As an example, any one of a silicon nitride (SiNₓ) film, a silicon oxide (SiOₓ) film, or a silicon oxynitride (SiOₓN_{y}) film may be used as the buffer layer 120. However, the buffer layer 120 is not necessarily required, and may be omitted depending on a type of the substrate 111 and a process condition.

The driving semiconductor layer 132 may be disposed on the buffer layer 120. The driving semiconductor layer 132 may be formed as a polycrystalline silicon film. In addition, the driving semiconductor layer 132 may include a channel region 135 that is not doped with impurities, and a source region 136 and a drain region 137 formed on both sides of the channel region 135, respectively, by p+ doping. In this case, a doped ionic material is a P-type impurity such as boron (B), and for example, B₂H₆ may be used as the doped ionic material. Here, such an impurity may be changed depending on a type of thin film transistor.

In an example embodiment, a thin film transistor with a P-channel metal oxide semiconductor (PMOS) structure using P-type impurities has been used as the driving transistor 20, but the disclosure is not limited thereto. For example, a thin film transistor with an N-channel metal oxide semiconductor (NMOS) structure or a complementary metal oxide semiconductor (CMOS) structure may be used as the driving transistor 20.

The driving transistor 20 illustrated in FIG. 3 may be a polycrystalline thin film transistor including a polycrystalline silicon film, but the switching transistor 10 not illustrated in FIG. 3 may be a polycrystalline thin film transistor or an amorphous thin film transistor including an amorphous silicon film.

The gate insulating film 140 including, e.g., silicon nitride (SiNₓ), silicon oxide (SiOₓ), or the like, may be disposed on the driving semiconductor layer 132. A gate wiring line including the driving gate electrode 155 may be formed on the gate insulating film 140. The gate wiring line may further include the gate line 151, the first capacitor plate 158, and other wiring lines. The driving gate electrode 155 may be disposed to overlap at least a portion of the driving semiconductor layer 132 (e.g., the channel region 135).

An interlayer insulating film 160 covering the driving gate electrode 155 may be disposed on the gate insulating film 140. The gate insulating film 140 and the interlayer insulating film 160 may have contact holes exposing the source region 136 and the drain region 137 of the driving semiconductor layer 132.

The interlayer insulating film 160 may include, e.g., silicon nitride (SiNₓ), silicon oxide (SiOₓ), or the like, like the gate insulating film 140.

A data wiring line including the driving source electrode 176 and the driving drain electrode 177 may be formed on the interlayer insulating film 160. The data wiring line may further include the data line 171, the common power line 172, the second capacitor plate 178, and other wiring lines. The driving source electrode 176 and the driving drain electrode 177 may be connected to the source region 136 and the drain region 137 of the driving semiconductor layer 132, respectively, through the contact holes of the interlayer insulating film 160 and the gate insulating film 140.

A planarization film 180 covering the data wiring lines 172, 176, 177, and 178 may be disposed on the interlayer insulating film 160. The planarization film 180 may serve to remove and planarize a step (or height difference) in order to increase luminous efficiency of the light emitting element 70 to be formed on the planarization film 180.

The planarization film 180 may have a contact hole 182 exposing a portion of the driving drain electrode 177.

The planarization film 180 may include, e.g., one or more of a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB).

In an embodiment, any one of the planarization film 180 and the interlayer insulating film 160 may be omitted.

The pixel electrode 710 of the light emitting element 70 may be disposed on the planarization film 180. For example, the display device may include one or more pixel electrodes 710 respectively disposed in the one or more pixels PX. In this case, the pixel electrodes 710 may be disposed to be spaced apart from each other. The pixel electrode 710 may be connected to the driving drain electrode 177 through the contact hole 182 of the planarization film 180.

A pixel defining film 190 having one or more openings 199 exposing the respective pixel electrodes 710 may be disposed on the planarization film 180. For example, the opening 199 of the pixel defining film 190 may be formed for each pixel PX. The pixel electrode 710 may be disposed to correspond to the opening 199 of the pixel defining film 190. However, the pixel electrode 710 is not necessarily disposed only in the opening 199 of the pixel defining film 190, and a portion of the pixel electrode 710 may be disposed below the pixel defining film 190 so as to overlap the pixel defining film 190. The pixel defining film 190 may correspond to a non-emission area of the pixel PX, and the opening 199 of the pixel defining film 190 may correspond to an emission area of the pixel PX. The pixel defining film 190 may be formed as an organic film including, e.g., an acrylic resin, an epoxy resin, a phenolic resin, a polyamide resin, a polyimide resin, or the like.

A spacer SPC may be disposed on the pixel defining film 190. For example, the spacer SPC may be disposed in the non-emission area of the pixel PX. The spacer SPC may serve to support a mask during a process of manufacturing the light emitting layer 720. The spacer SPC may be formed as an organic film including, e.g., an acrylic resin, an epoxy resin, a phenolic resin, a polyamide resin, a polyimide resin, or the like.

The pixel defining film 190 and the spacer SPC may be formed integrally with (or may be integral with) each other through a photolithography process or a photo-etching process. For example, the pixel defining film 190 and the spacer SPC may be formed together through a halftone exposure process. However, the disclosure is not limited thereto, and for example, the pixel defining film 190 and the spacer SPC may be formed sequentially or separately, and may be formed using different materials.

The light emitting layer 720 may be disposed on the pixel electrode 710, and the common electrode 730 may be disposed on the light emitting layer 720.

The light emitting layer 720 may be disposed between the pixel electrode 710 and the common electrode 730 within the opening 199 of the pixel defining film 190 and provide light. The common electrode 730 may be disposed on the organic light emitting layer 720, the pixel defining film 190, and the spacer SPC.

The light emitting layer 720 may include, e.g., a low-molecular organic material or a high-molecular organic material. The light emitting layer 720 may be formed as multiple films including one or more of a light providing layer, a hole injection layer HIL, a hole transporting layer HTL, an electron transporting layer ETL, and an electron injection layer EIL. In case that the light emitting layer 720 includes all of the light providing layer, the hole injection layer HIL, the hole transporting layer HTL, the electron transporting layer ETL, and the electron injection layer EIL, the hole injection layer may be disposed on the pixel electrode 710, which is the positive electrode, and the hole transporting layer, the light providing layer, the electron transporting layer, and the electron injection layer may be sequentially stacked on the hole injecting layer.

The light emitting layer 720 may have been disposed only within the opening 199 of the pixel defining film 190 in FIG. 3, but is not limited thereto. For example, the light emitting layer 720 may be formed on the pixel electrode 710 within the opening 199 of the pixel defining film 190 and/or may be disposed between the pixel defining film 190 and the common electrode 730. The light emitting layer 720 may include, e.g., an organic material to emit light of a color (e.g., a selectable or predetermined color). For example, the light emitting layer 720 may include a hole transporting layer, an organic material layer, and an electron transporting layer. The organic material layer may include a host and a dopant. The organic material layer may include a material emitting predetermined light, and may be formed using a phosphorescent material or a fluorescent material.

Each of the pixel electrode 710 and the common electrode 730 may include, e.g., a transparent conductive material and/or a transflective or reflective conductive material. Depending on a type of material forming the pixel electrode 710 and the common electrode 730, the display device may be any one of a top emission-type display device, a bottom emission-type display device, or a double-sided emission-type display device.

The display device according to an example embodiment may be a top emission-type display device. For example, the light emitting clement 70 may display an image by emitting light in a direction toward an encapsulation layer ENC (e.g., a third direction DR3).

A material such as indium tin oxide (ITO), indium zinc oxide (IZO), zinc oxide (ZnO), or indium oxide (In₂O₃) may be used as the transparent conductive material. A material such as lithium (Li), calcium (Ca), lithium fluoride/calcium (LiF/Ca), lithium fluoride/aluminum (LiF/Al), aluminum (Al), silver (Ag), magnesium (Mg), or gold (Au) may be used as the reflective material and the transflective material.

The encapsulation layer ENC may be disposed on the common electrode 730. The encapsulation layer ENC may include at least one inorganic film TFEL and TFE3 in order to prevent oxygen or moisture from permeating into the light emitting element 70. The encapsulation layer ENC may include at least one organic film TFE2 in order to protect the light emitting clement 70 from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode 730, the encapsulation organic film TFE2 may be disposed on the first encapsulation inorganic film TFE1, and the second encapsulation inorganic film TFE3 may be disposed on the encapsulation organic film TFE2. For example, the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. For example, the encapsulation organic film TFE2 may be an organic film including an acrylic resin, an epoxy resin, a phenolic resin, a polyamide resin, a polyimide resin, a monomer, or the like.

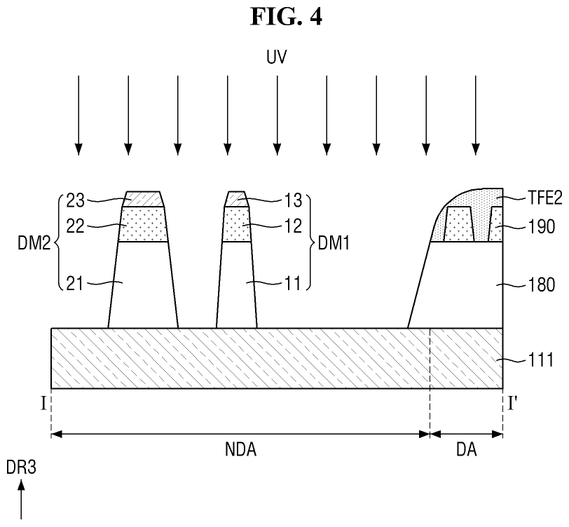

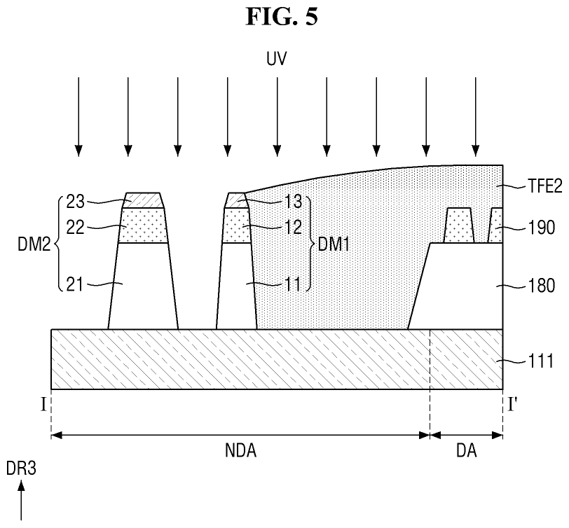

FIG. 4 is a schematic cross-sectional view of the display device according to an example embodiment taken along line I-I′ of FIG. 1, and FIG. 5 is a schematic cross-sectional view of the display device according to an example embodiment taken along line I-I′ of FIG. 1.

As illustrated in FIG. 4, the first dam DM1 may include a first insulating film 11, a second insulating film 12, and a third insulating film 13 that are sequentially disposed on the substrate 111 in the third direction DR3.

The first insulating film 11 of the first dam DM1 may be disposed on the substrate 111. The first insulating film 11 and the planarization film 180 may be disposed on a same layer. The first insulating film 11 and the planarization film 180 may include a same material.

The second insulating film 12 of the first dam DM1 may be disposed on the first insulating film 11. The second insulating film 12 and the pixel defining film 190 may be disposed on a same layer. The second insulating film 12 and the pixel defining film 190 may include a same material.

The third insulating film 13 of the first dam DM1 may be disposed on the second insulating film 12. The third insulating film 13 and the spacer SPC may be disposed on a same layer. The third insulating film 13 and the spacer SPC or pixel defining film 190 may include a same material. As described above, the spacer SPC and the pixel defining film 190 may include a same material and be formed integrally with each other or may include different materials, and a structure of the first dam DM1 in case that the spacer SPC and the pixel defining film 190 include different materials has been illustrated in FIG. 4. In other words, the second insulating film 12 and the third insulating film 13 of the first dam DM1 may include different materials, and in this case, the second insulating film 12 and the pixel defining film 190 may include a same material and the third insulating film 13 and the spacer SPC may include a same material. In case that the pixel defining film 190 and the spacer SPC include a same material, the second insulating film 12 and the third insulating film 13 described above may also include a same material.

The second dam DM2 may include a first insulating film 21, a second insulating film 22, and a third insulating film 23 that are sequentially disposed on the substrate 111 in the third direction DR3. The first insulating film 21, the second insulating film 22, and the third insulating film 23 of the second dam DM2 may be substantially identical or similar to the first insulating film 11, the second insulating film 12, and the third insulating film 13 of the first dam DM1 described above, respectively.

The first dam DM1 and the second dam DM2 may have the same height. In another example embodiment, the first dam DM1 and the second dam DM2 may have different heights. For example, the second dam DM2 may have a greater height than the first dam DM1. Here, the height may refer to a size in the third direction DR3 based on an upper surface of the substrate 111.

As illustrated in FIG. 4, the encapsulation organic film TFE2 may be disposed on the pixel defining film 190. Here, the first encapsulation inorganic film TFE1 described above may be disposed between the encapsulation organic film TFE2 and the pixel defining film 190.

Since the encapsulation organic film TFE2 may include a transparent material, even though the encapsulation organic film TFE2 is applied onto the substrate 111 and then cured, it is not easy to confirm a position of the encapsulation organic film TFE2. For example, in case that the encapsulation organic film TFE2 includes a material including a monomer, the encapsulation organic film TFE2 has a transparent color, and thus, it is not easy to grasp a spread degree of the encapsulation organic film TFE2 even using an optical inspection device.

As illustrated in FIG. 4, in case that an edge of the encapsulation organic film TFE2 is positioned within the display area DA of the substrate 111, the encapsulation layer ENC including such an encapsulation organic film TFE2 may normally perform the above-described function (e.g., a function of preventing oxygen, moisture, dust, or the like, from permeating into the light emitting element 70).

However, as illustrated in FIG. 5, in case that an edge of the encapsulation organic film TFE2 is in contact with the first dam DM1 or is formed between the first dam DM1 and the second dam DM2 beyond the first dam DM1, the encapsulation organic film TFE2 may not normally perform the above-mentioned function. Accordingly, it is necessary to confirm the spread degree of the encapsulation organic film TFE2 in order to accurately decide whether or not the encapsulation layer ENC is defective.

According to an example embodiment, ultraviolet (UV) may be irradiated to the encapsulation organic film TFE2 so that the encapsulation organic film TFE2 that is transparent may be accurately detected by the optical inspection device. Here, the ultraviolet may be, for example, near ultraviolet (near UV).

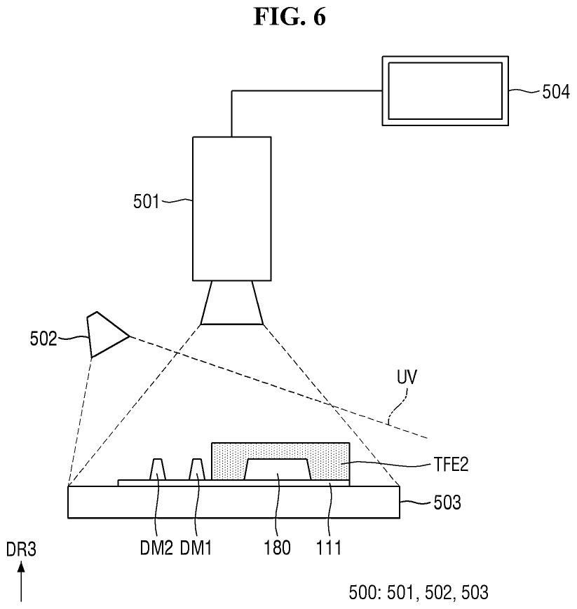

For example, in a state in which the ultraviolet is irradiated to the encapsulation organic film TFE2, an image of the encapsulation organic film TFE2 may be captured by the optical inspection device. This will be described in detail below with reference to FIG. 6.

FIG. 6 is a schematic view for describing a method for inspecting a spread degree of an encapsulation organic film TFE2 according to an example embodiment.

An optical inspection device 500 may include a stage 503, an image capturing unit 501, and/or an ultraviolet irradiating unit 502, as illustrated in FIG. 6.

First, the substrate 111 on which the encapsulation organic film TFE2 is formed may be disposed on the stage 503.

Next, ultraviolet may be irradiated from the ultraviolet irradiating unit 502 toward the stage 503. The ultraviolet UV from the ultraviolet irradiating unit 502 may be irradiated to an entire surface of the substrate 111 including the encapsulation organic film TFE2 or may be selectively irradiated to the non-display area NDA of the substrate 111. The ultraviolet UV irradiated to the encapsulation organic film TFE2 may be absorbed by the encapsulation organic film TFE2.

Next, in a state where the ultraviolet UV described above are irradiated onto the encapsulation organic film TFE2, an image of the encapsulation organic film TFE2 may be captured by the image capturing unit 501. The captured image may be transmitted to a display device 504. Here, the image capturing unit 501 may include a camera.

In an embodiment, the encapsulation organic film TFE2 displayed on the display device 504 may have an opaque color. For example, the encapsulation organic film TFE2 in the image displayed on the display device 504 may have a black or black-based color. This is because the monomer of the encapsulation organic film TFE2 may transmit visible light therethrough but absorb the ultraviolet UV. Accordingly, the encapsulation organic film TFE2 that has absorbed the ultraviolet UV may have an opaque color in the captured image.

Accordingly, a user may readily detect a spread degree of the encapsulation organic film TFE2 and/or a position of the edge (or a boundary portion) of the encapsulation organic film TFE2 in the image displayed on the display device 504 with the naked eye. Accordingly, it may be accurately decided whether or not the encapsulation layer ENC including the encapsulation organic film TFE2 is defective.

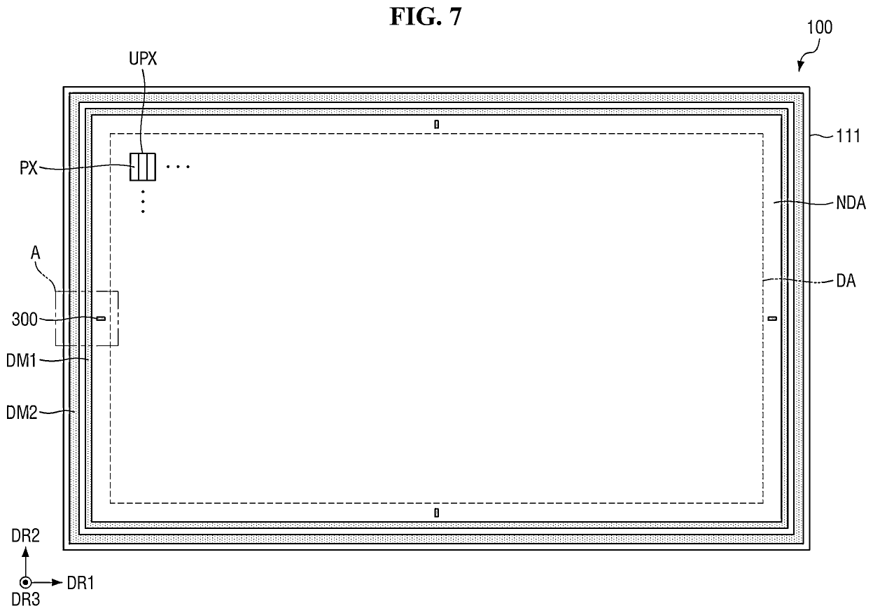

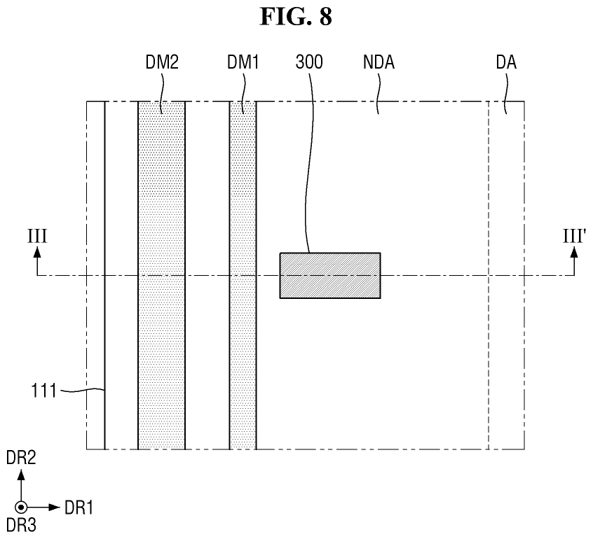

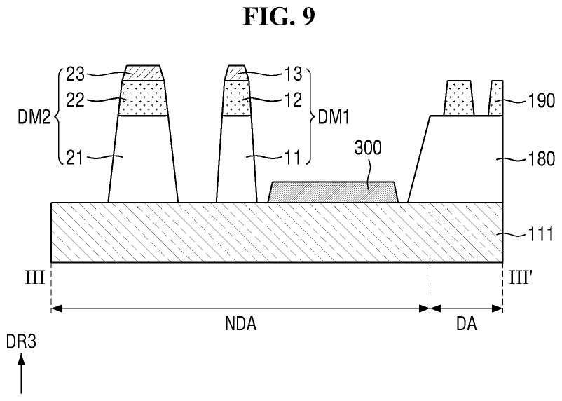

FIG. 7 is a schematic plan view of a display device according to an example embodiment, FIG. 8 is a schematic enlarged view of part A of FIG. 7, and FIG. 9 is a schematic cross-sectional view taken along line III-III′ of FIG. 8.

A display device of FIG. 7 may be different from the display device of FIG. 1 described above in that it further includes a detection pattern 300, and such a difference will be mainly described below.

A display panel 100 of the display device may include the detection pattern 300, as illustrated in FIG. 7.

The detection pattern 300 may be used to detect a position of the encapsulation organic film TFE2 described above. The detection pattern 300 may be disposed in the non-display area NDA of the substrate 111. For example, the detection pattern 300 may be disposed in the non-display area NDA between the first dam DM1 and the display area DA.

In plan view, the detection pattern 300 may have a rectangular shape in which it extends toward the first dam DM1. The detection pattern 300 may have a black color or a black-based dark color.

For example, the detection pattern 300 may include a metal material such as chromium (Cr) or molybdenum (Mo), black ink, black dye, or the like. The detection pattern 300 may include an inorganic black pigment or an organic black pigment. The inorganic black pigment may be carbon black, and the organic black pigment may include at least one of lactam black, perylene black, and aniline black, but the disclosure is not limited thereto. For example, the detection pattern 300 may include a material having a color other than the black color.

As illustrated in FIG. 7, the detection patterns 300 may be disposed on the left, right, upper, and lower sides of the substrate 111, respectively. In this case, one or more detection patterns 300 may be disposed on the left side of the substrate 111, one or more detection patterns 300 may be disposed on the right side of the substrate 111, one or more detection patterns 300 may be disposed on the upper side of the substrate 111, and one or more detection patterns 300 may be disposed on the lower side of the substrate 111.

As illustrated in FIG. 9, a height (or a thickness) of the detection pattern 300 may be smaller than a height (or a thickness) of the first dam DM1 or a height (or a thickness) of the second dam DM2. Here, the height (or the thickness) may refer to a size measured in the third direction DR3 based on the upper surface of the substrate 111.

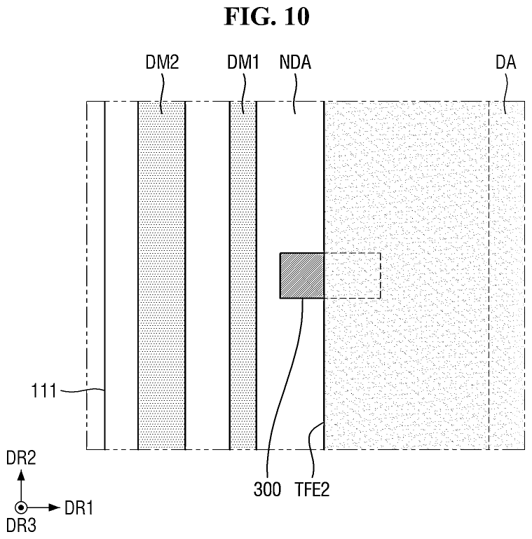

FIG. 10 is a schematic view for describing a method for deciding a position of an encapsulation organic film TFE2 using a detection pattern 300 of FIG. 8.

First, the detection pattern 300 may be formed on the substrate 111.

The position of the encapsulation organic film TFE2 (e.g., the position of the edge of the encapsulation organic film TFE2) may be decided more accurately based on the detection pattern 300 in the captured image described above. For example, the position of the edge of the encapsulation organic film TFE2 may be decided based on an overlapping portion of the detection pattern 300 that overlaps the encapsulation organic film TFE2 and a non-overlapping portion of the detection pattern 300 that does not overlap the encapsulation organic film TFE2, in the captured image.

For example, as illustrated in FIG. 10, the detection pattern 300 may overlap the encapsulation organic film TFE2. For example, a portion of the detection pattern 300 may overlap the encapsulation organic film TFE2, and the other portion of the detection pattern 300 except for a portion of the detection pattern 300 may not overlap the encapsulation organic film TFE2. Here, a portion of the detection pattern 300 that overlaps the encapsulation organic film TFE2 (a dotted line portion of the detection pattern 300) may be defined as an overlapping portion, and a portion of the detection pattern 300 that does not overlap the encapsulation organic film TFE2 may be defined as a non-overlapping portion. In case that an image of the substrate 111 including the detection pattern 300 and the encapsulation organic film TFE2 is captured by the image capturing unit 501 of the optical inspection device 500, the overlapping portion of the detection pattern 300 may be displayed blurrier than the non-overlapping portion of the detection pattern 300 in the captured image. In other words, the overlapping portion of the detection pattern 300 may be displayed less clearly than the non-overlapping portion of the detection pattern 300. This is because the overlapping portion of the detection pattern 300 is covered by the encapsulation organic film TFE2. As described above, in the state in which the ultraviolet described above is irradiated to the encapsulation organic film TFE2, the image of the substrate 111 including the detection pattern 300 and the encapsulation organic film TFE2 may be captured by the image capturing unit 501 of the optical inspection device 500.

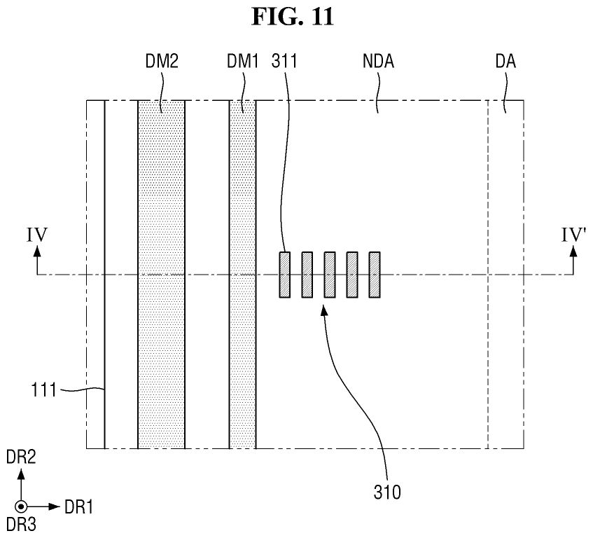

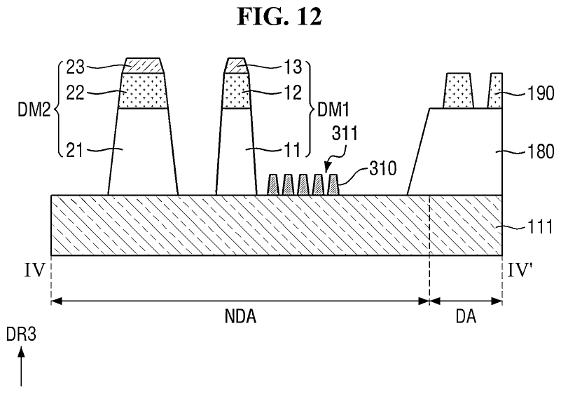

FIG. 11 is a schematic enlarged view of a portion of a display device according to an example embodiment, and FIG. 12 is a schematic cross-sectional view taken along line IV-IV′ of FIG. 11.

A detection pattern 310 of a display device of FIGS. 11 and 12 may be different at least in its form, shape, and/or structure from the detection pattern 300 of FIGS. 8 and 9, and such a difference will be mainly described below.

As illustrated in FIGS. 11 and 12, the detection pattern 310 may include multiple sub-patterns 311 disposed in the non-display area NDA of the substrate 111. The sub-patterns may be arranged in a row in a direction (e.g., the first direction DR1). The sub-patterns 311 may be disposed to be spaced apart from each other at regular intervals. The respective sub-patterns 311 may have the same size and shape. The respective sub-patterns 311 may have a rectangular shape.

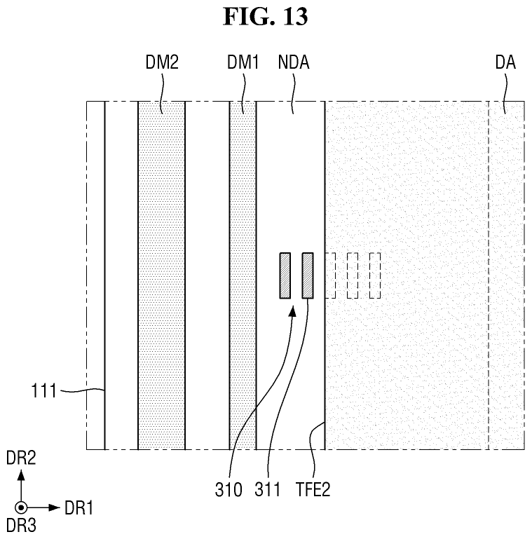

FIG. 13 is a schematic view for describing a method for deciding a position of an encapsulation organic film TFE2 using a detection pattern 310 of FIG. 11.

As illustrated in FIG. 13, at least some of the sub-patterns 311 of the detection pattern 310 may overlap the encapsulation organic film TFE2. For example, some of the sub-patterns 311 may overlap the encapsulation organic film TFE2, and the other sub-patterns 311 except for some of the plurality of sub-patterns 311 may not overlap with the encapsulation organic film TFE2. Here, the sub-patterns 311 that overlap the encapsulation organic film TFE2 among the plurality of sub-patterns 311 may be defined as overlapping patterns, and the sub-patterns 311 that do not overlap the encapsulation organic film TFE2 among the plurality of sub-patterns 311 may be defined as non-overlapping patterns. In case that an image of the substrate 111 including the detection pattern 310 and the encapsulation organic film TFE2 is captured by the image capturing unit 501 of the optical inspection device 500, the overlapping patterns may be displayed blurrier than the non-overlapping patterns in the captured image. In other words, the overlapping patterns may be displayed less clearly than the non-overlapping patterns. This is because the overlapping patterns are covered by the encapsulation organic film TFE2. As described above, in the state in which the ultraviolet described above is irradiated to the encapsulation organic film TFE2, the image of the substrate 111 including the detection pattern 310 and the encapsulation organic film TFE2 may be captured by the image capturing unit 501 of the optical inspection device 500.

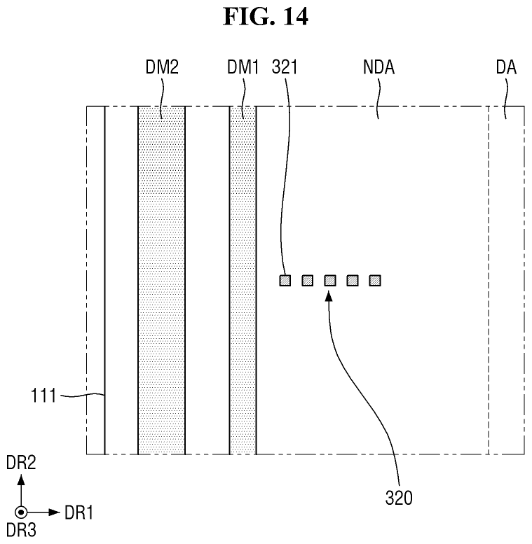

FIG. 14 is a schematic enlarged view of a portion of a display device according to an example embodiment.

A detection pattern 320 of a display device of FIG. 14 may be different at least in its form, shape, and/or structure from the detection pattern 310 of FIG. 11, and such a difference will be mainly described below.

As illustrated in FIG. 14, the detection pattern 320 may include multiple sub-patterns 321, each of which may have a square shape.

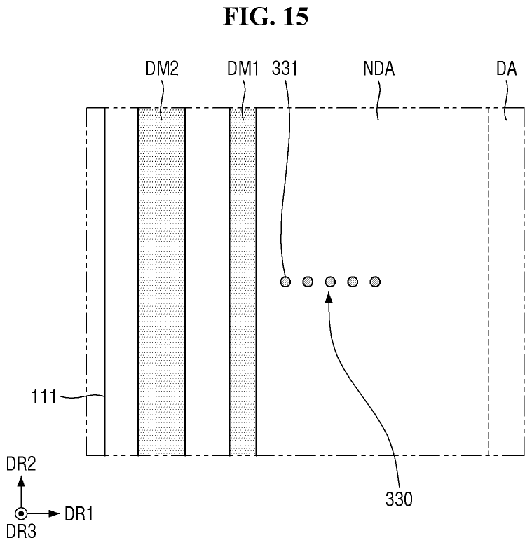

FIG. 15 is a schematic enlarged view of a portion of a display device according to an example embodiment.

A detection pattern 330 of a display device of FIG. 15 may be different at least in its form, shape, and/or structure from the detection pattern 310 of FIG. 11, and such a difference will be mainly described below.

As illustrated in FIG. 15, the detection pattern 330 may include multiple sub-patterns 331, each of which may have a circular shape.

The sub-pattern 331 may have various shapes in addition to the shape described above. For example, the sub-pattern 331 may have various shapes such as an elliptical shape or a triangular shape.

It will be able to be understood by one of ordinary skill in the art to which the disclosure belongs that the disclosure may be implemented in other specific forms without changing the technical spirit or essential features of the disclosure. Therefore, it is to be understood that the example embodiments described above are illustrative rather than being restrictive in all aspects. It is to be understood that the scope of the disclosure are defined by the claims rather than the detailed description described above and all modifications and alterations derived from the claims and their equivalents fall within the scope of the disclosure.

What is claimed is:

1. A display device comprising:
a display area and a non-display area;
a pixel electrode disposed on a substrate in the display area;
a light emitting layer disposed on the pixel electrode;
a common electrode disposed on the light emitting layer;
an encapsulation organic film disposed on the common electrode; and
a detection pattern disposed in the non-display area.

2. The display device of claim 1, wherein at least a portion of the detection pattern overlaps the encapsulation organic film.

3. The display device of claim 1, wherein the detection pattern has a black color.

4. The display device of claim 1, wherein the detection pattern includes at least one of chromium, molybdenum, black ink or black dye, carbon black, lactam black, perylene black, and aniline black.

5. The display device of claim 1, wherein the detection pattern includes a plurality of sub-patterns spaced apart from each other.

6. The display device of claim 1, further comprising:
a dam disposed in the non-display area.

7. The display device of claim 6, wherein the dam is disposed in the non-display area so as to surround the display area.

8. The display device of claim 7, wherein the dam includes:
a first dam disposed in the non-display area so as to surround the display area; and a second dam disposed in the non-display area so as to surround the first dam.

9. The display device of claim 6, wherein the detection pattern is disposed between the display area and the dam.

10. The display device of claim 6, wherein the detection pattern has a smaller height or a smaller thickness than the dam.

11. The display device of claim 1, wherein the encapsulation organic film includes a monomer.

12. A method for detecting a position of an encapsulation film of a display device, comprising:
preparing a display panel including a substrate, a pixel electrode disposed on the substrate, a light emitting layer disposed on the pixel electrode, a common electrode disposed on the light emitting layer, and an encapsulation organic film disposed on the common electrode;
irradiating ultraviolet to the encapsulation organic film;
capturing an image of the encapsulation organic film in a state in which the ultraviolet is irradiated to the encapsulation organic film; and
confirming the encapsulation organic film based on the captured image.

13. The method of claim 12, wherein the irradiating of the ultraviolet includes irradiating near ultraviolet.

14. The method of claim 12, wherein in the confirming of the encapsulation organic film, a position of an edge of the encapsulation organic film on the substrate is confirmed in the captured image.

15. The method of claim 12, further comprising: forming a detection pattern in a non-display area.

16. The method of claim 15, wherein in the confirming of the encapsulation organic film, a position of an edge of the encapsulation organic film on the substrate is confirmed based on the detection pattern in the captured image.

17. The method of claim 16, wherein in the confirming of the encapsulation organic film, the position of the edge of the encapsulation organic film is confirmed based on an overlapping portion of the detection pattern that overlaps the encapsulation organic film and a non-overlapping portion of the detection pattern that does not overlap the encapsulation organic film in the captured image.

18. The method of claim 17, wherein the overlapping portion of the detection pattern is displayed blurrier than the non-overlapping portion of the detection pattern in the captured image.

19. The method of claim 12, wherein the encapsulation organic film includes a monomer.

20. The method of claim 15, wherein the detection pattern includes at least one of chromium, molybdenum, black ink or black dye, carbon black, lactam black, perylene black, and aniline black.
